(19) United States
(12) Patent Application Publication
(10) Pub. No.: US 2025/0023656 A1
(43) Pub. Date: Jan. 16, 2025

(54) SYSTEM AND METHOD FOR INTELLIGENT POWER MANAGEMENT

(71) Applicant: IXI Technology Holdings, Inc., Yorba Linda, CA (US)

(72) Inventors: Byron del Castillo, Eastvale, CA (US); Michael Dekoker, Eastvale, CA (US); Daniel Hyman, Long Beach, CA (US); Michael Carter, Laguna Niguel, CA (US)

(21) Appl. No.: 18/773,298

(22) Filed: Jul. 15, 2024

Related U.S. Application Data
(60) Provisional application No. 63/526,961, filed on Jul. 14, 2023.

(51) Int. Cl. H04K 1/00; H03F 1/32; H03F 3/24; H04B 1/04; H04B 1/715

(52) U.S. Cl. CPC H04K 1/003; H03F 1/3241; H03F 3/245; H04B 1/04; H04B 1/715; H03F 2200/451; H04B 2201/71323

(57) ABSTRACT

A system and method for enhancing RF signal jamming. The method includes steps of pre-distorting an input signal to define a pre-distorted signal; adjusting a voltage of a power supply of a power amplifier based upon the pre-distorted signal to envelope track; power sequencing the power amplifier to power up and power down the amplifier; achieve a low probability of intercept of the signal, and transmitting the adjusted signal. Systems are other methods are likewise disclosed.

### BACKGROUND OF THE DISCLOSURE

This application claims from priority from U.S. Patent App. Ser. No. 63/526,961 entitled “System and Method for Intelligent Power Management” filed Jul. 14, 2023, the entire disclosure of which is hereby incorporated by reference in its entirety.

### BACKGROUND OF THE DISCLOSURE

### 1. Field of the Disclosure

The disclosure relates in general to a system and method of power management, and more particularly, to a system and method for enhancing the performance of radio frequency (RF) signal jamming systems by combining the techniques of pre-distortion, envelope tracking, power sequencing, and low probability of intercept (LPI) protocols.

### 2. Background Art

RF signal jamming systems and devices generally incorporate the process of amplifying a modulated signal through the use of a power amplifying system or device. The amplification process leads to amplification of not only the desirable signal, but also the amplification of distortions or imperfections in the underlying modulated signal to be amplified.

Problematically, many communication protocols, especially for 4G and 5G communication, among others, are increasingly difficult to jam. Such jamming may be desirable in a counter drone or other situation (with the disclosure not being limited to such an environment). Nevertheless, the difficulty in the communication protocols, as well as the communication standards at such frequencies, render consistent and effective jamming quite difficult.

It would be advantageous to improve RF signal jamming systems in such environments and other difficult environments.

### SUMMARY OF THE DISCLOSURE

The disclosure, in one aspect is directed to a method, stored on a non-transitory medium and executed by a processor for enhancing an RF jamming system. The method comprises the steps of: pre-distorting an input signal to compensate for non-linear distortion in at least one power amplifier to define a pre-distorted signal; adjusting a voltage of a power supply of the at least one power amplifier based upon the pre-distorted signal; power sequencing the at least one power amplifier to power up and power down the at least one amplifier; adjusting the pre-distorted signal to achieve a low probability of intercept to define an adjusted signal; and transmitting the adjusted signal.

In some configurations, the step of pre-distorting further comprises the step of predicting the pre-distortion utilizing machine learning (AI).

In some configurations, the step of pre-distorting further comprises the step of training the machine learning by providing a dataset of modulated signals to predict an optimal pre-distortion for the input signal to define the pre-distorted signal.

In some configurations, the step of pre-distorting further comprises the step of utilizing a neural network.

In some configurations, the step of adjusting the voltage further comprises the step of generating, digitally or analog, a variable voltage based upon the pre-distorted signal;

In some configurations, the step of adjusting the voltage comprise the step of adjusting the power supply voltage in real-time based upon an amplitude of the pre-distorted signal.

In some configurations, the step of adjusting the voltage comprises the steps of: tracking an envelope of the waveform and adjusting the power supply voltage in real-time based on at least one characteristic of the envelope.

In some configurations, the step of adjusting further comprises the step of determining the adjustment utilizing machine learning (AI).

In some configurations, the step of adjusting the pre-distorted signal to achieve the low probability of intercept comprises at least one of the steps of frequency hopping and spread spectrum transmitting.

In some configurations, the steps of frequency hopping and spread spectrum transmitting are adjusted on a real time basis.

In some configurations, the step of adjusting the pre-distorted signal to achieve the low probability of intercept further comprises the step of transmitting the adjusted signal through low power or the step of transmitting the adjusted signal through short burst transmissions.

In some configurations, the step of adjusting the pre-distorted signal to achieve the low probability of intercept further comprises the step of focusing the adjusted signal through the use of directional antennas.

In some configurations, the step of adjusting the pre-distorted signal to achieve the low probability of intercept further comprises the step of applying beamforming to, in turn, reduce detectability of the adjusted signal when transmitted.

In some configurations, the method includes the step of generating a modulated signal through the use of a signal generator prior to the step of pre-distorting, and wherein the modulated signal is the input signal.

In some configurations, the modulated signal includes multiple channels.

In some configurations, the step of pre-distorting further includes the step of adapting to at least one change in the at least one power amplifier.

In some configurations, the step of pre-distorting further includes the steps of: monitoring an output of the at least one power amplifier; and adjusting the pre-distorting based upon the monitored output of the at least one power amplifier.

In some configurations, the step of adjusting the voltage and the step of power sequencing utilize digital signal processing.

In some configurations, the step of power sequencing further comprises the step of preventing an overshoot and an undershoot.

In some configurations, the step of preventing an overshoot and an undershoot further comprises the steps of smoothly ramping up and smoothly ramping down the at least one power amplifier.

In some configurations, the input signal may comprise a plurality of input signals, resulting in a plurality of pre-distorted signals and a plurality of adjusted signals.

In another aspect of the disclosure, the disclosure is directed to a system system for enhancing an RF jamming system. The system includes a pre-distorting module, a voltage adjuster, a power sequencer, a lower probability of intercept module and a transmitter. The pre-distorting module is structurally configured to pre-distort an input signal to compensate for non-linear distortion in at least one power amplifier to define a pre-distorted signal. The voltage adjuster is structurally configured to adjust the voltage of a power supply of the at least one power amplifier based upon the pre-distorted signal. The power sequencer is structurally configured to sequence the at least one power amplifier to power up and power down the at least one amplifier. The low probability of intercept module is structurally configured to adjust the pre-distorted signal to define an adjusted signal. The transmitter is structurally configured to transmit the adjusted signal.

In another aspect of the disclosure, the disclosure is directed to a method, stored on a non-transitory medium and executed by a processor for enhancing an RF jamming system. The method comprises the steps of: pre-distorting an input signal to compensate for non-linear distortion in at least one power amplifier to define a pre-distorted signal utilizing machine learning (AI); adjusting a voltage of a power supply of the at least one power amplifier based upon the pre-distorted signal utilizing machine learning (AI); power sequencing the at least one power amplifier to power up and power down the at least one amplifier; adjusting the pre-distorted signal to achieve a low probability of intercept to define an adjusted signal; and transmitting the adjusted signal.

### BRIEF DESCRIPTION OF THE DRAWINGS

The disclosure will now be described with reference to the drawings wherein:

FIG. 1 of the drawings is a schematic representation of a system which can be used for enhancing the performance of a radio frequency signal jamming system;

FIG. 2 of the drawings is a block diagram of a configuration of a method for enhancing the performance of a radio frequency signal jamming system;

FIG. 3 of the drawings is a block diagram of a configuration of a pre-distortion circuit for correcting non-linear distortion in a power amplifying system;

FIG. 4 of the drawings is a block diagram for using artificial intelligence to form a pre-distortion circuit for correcting non-linear distortion in a power amplifying system;

FIG. 5 of the drawings is a block diagram of an circuit for correcting non-linear distortion in a power amplifying system; and

FIG. 6 of the drawings is an exemplary schematic representation of a general purpose computer.

### DETAILED DESCRIPTION OF THE DISCLOSURE

While this disclosure is susceptible of embodiment in many different forms, there is shown in the drawings and described herein in detail a specific embodiment(s) with the understanding that the present disclosure is to be considered as an exemplification and is not intended to be limited to the embodiment(s) illustrated.

It will be understood that like or analogous elements and/or components, referred to herein, may be identified throughout the drawings by like reference characters. In addition, it will be understood that the drawings are merely schematic representations of the disclosure.

The disclosure is directed to a system and method for enhancing the performance of radio frequency (RF) signal jamming devices by combining techniques of pre-distortion, power sequencing, and low probability of intercept (LPI) protocols. The system and method may use any or all of the techniques as aforementioned and described herein and may further incorporate the use of machine learning or artificial intelligence (AI) in performance of the same.

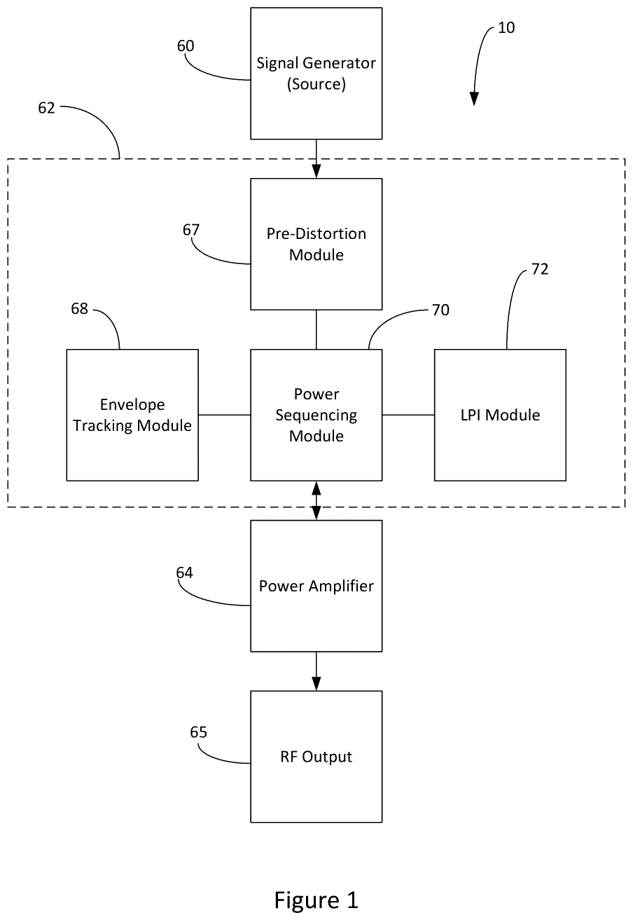

Among other applications, one application may include, but not be limited to use in association with an RF signal jamming system, which, among other things, can be used to counter drones, in, for example, a theater of battle. One such system may take the configuration shown schematically in FIG. 1. Such a system 10 includes signal generator 60, adaptive module 62, power amplifier module 64 which provides RF output 65. The adaptive module 62 includes pre distortion module 67, envelope tracking module 68, power sequencing module 70, and LPI module 72. The operation of each of the foregoing is discussed hereinafter in association with, for example, counter-drone environments. It will be understood that the disclosure is not limited thereto, and not limited to use in counter-drone environments. However, it is known that counter-drone environments tend to be one of the more difficult environments due to the dynamics of the signal communication between drones and between the drone and the controller.

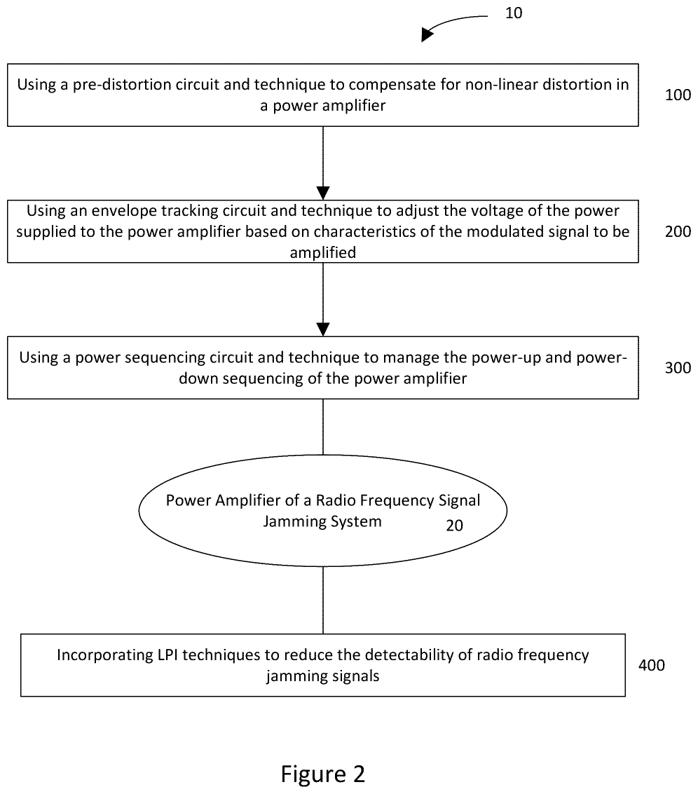

Referring now to FIG. 2, the method 10 for enhancing the performance of an RF signal jamming system comprises: using a pre-distortion circuit and technique 100 to compensate for non-linear distortion in a power amplifier; using an envelope tracking circuit and technique 200 to adjust the voltage of the power supplied to the power amplifier based on characteristics of the modulated signal to be amplified; using a power sequencing circuit and technique 300 to manage the power-up and power-down sequencing of the power amplifier or multiple power amplifiers; applying these techniques to an amplifier or multiple amplifiers 20 of a RF signal jamming system or device; and further incorporating low probability of intercept (LPI) techniques 400 to reduce the detectability and further enhance the efficiency of radio frequency jamming signals.

The method and system of this application may include any or all of the circuits and techniques as previously mentioned and may further incorporate a single power amplifier 20 or multiple power amplifiers 20. In some configurations, the method 10 may correspond to a RF signal jamming system which comprises multiple power amplifiers 20, thus the power sequencing technique 300 may direct the power-up and power-down of multiple power amplifying systems and correlating pre-distortion circuits 100 and envelope tracking circuits 200.

A pre-distortion technique 100 may be used to compensate and correct for non-linear distortion that occurs when amplifying modulated signals, wherein distortion may be caused by factors including but not limited to memory effects, power supply ripples, and temperature variations. The technique of signal pre-distortion works by monitoring the characteristic of a modulated signal to be amplified and applying an inverse distortion signal which counteracts the distortion that occurs during amplification, this may be referred to as input signal pre-distortion.

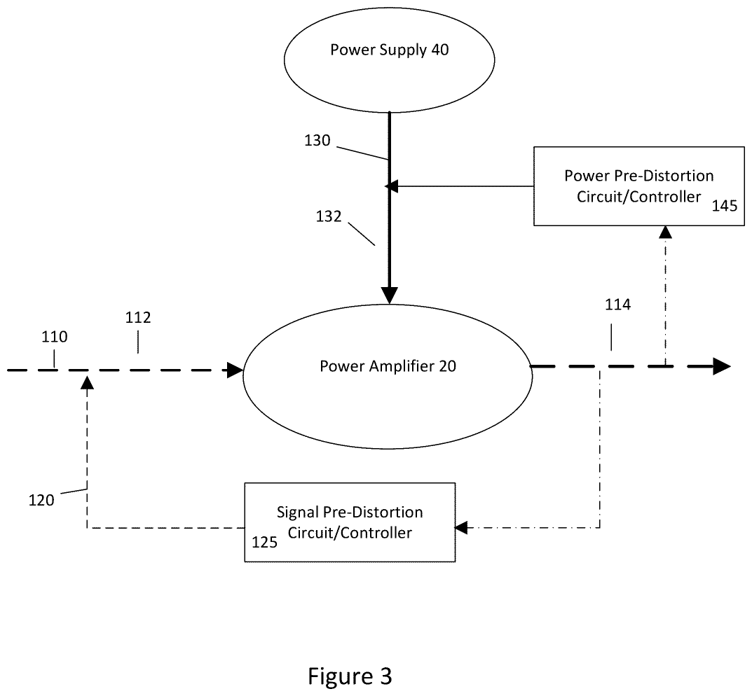

With reference to FIG. 3, the incoming modulated signal 110 is mixed with an inverse distortion signal 120 which counteracts the distortion that would otherwise be generated during the process of amplifying signal 110. This mixing results in an altered signal 112 entering the power amplifier 20. The characteristics of the inverse distortion signal 120 are determined by monitoring the output signal 114 of the power amplifier 20 and calculating/forming an appropriate inverse distortion signal accordingly. In some configurations, the characteristics of the inverse distortion signal 120 may be determined based upon the incoming signal 110 and output signal 114 of the power amplifier. The inverse distortion signal 120 is calculated and produced by the signal pre-distortion circuit and controller 125. In some configurations, the method may rely on artificial intelligence and machine learning techniques, as shown in FIG. 3 and as further described below, so as to optimize the method based upon repeated use and training of the system. Such training is understood by those of skill in the art.

The example embodiment of FIG. 3 considers that the original modulated signal 110 is generated by a waveform generator and then subsequently modified through the mixing of the inverse distortion signal 120 to obtain the altered signal 112. It is contemplated that in alternative embodiments of the disclosed subject matter that an altered signal may be generated directly by a waveform generator directly as part of the generation process and control commands used to generate the waveform. In at least one of such embodiments, the control commands used to generate the waveform are digital control commands supplied by a microprocessor component in a manner consistent with the engineering art of multidimensional digital pre-distortion. In at least one other embodiment, the control commands used to generate the waveform are analog control commands supplied by a circuit such as a feedback operational amplifier circuit configured for analog control and/or a digital to analog converter (ADC). These control commands may optionally incorporate signal conditioning circuitry such as filters to provide an appropriate signal to the waveform generation circuitry.

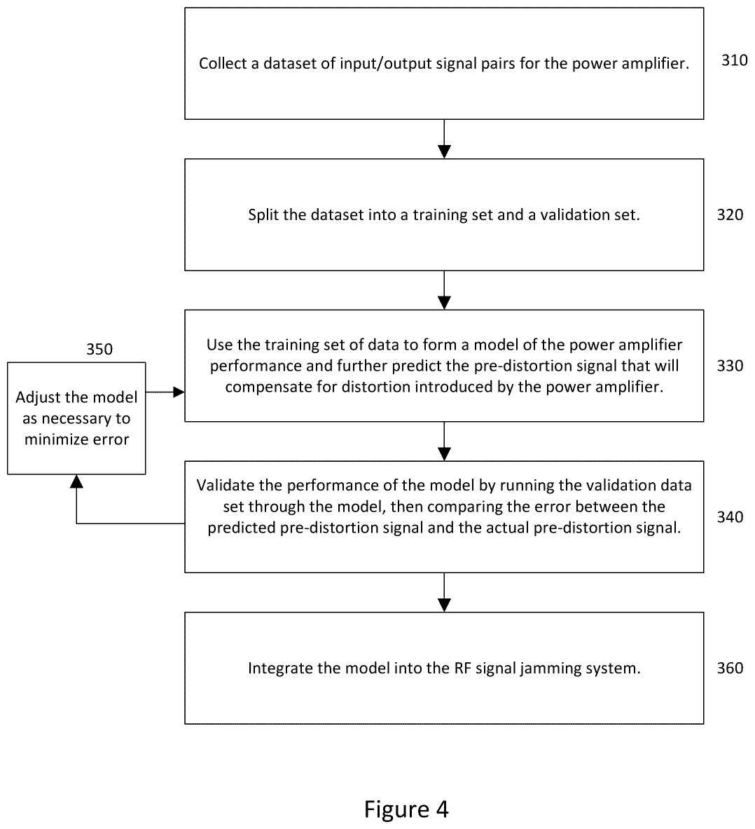

Pre-distortion 100 may also be applied by controlling the power or voltage which is supplied to the power amplifier 20. In power control pre-distortion, the power supply output 130 from the power supply 40 is adjusted to compensate for non-linearities caused by the power amplifying device or system 20. The step of pre-distortion may include an analog or digital feedback loop that monitors the output signal 114 of the power amplifier and adjusts the power supply output 130 accordingly to provide a modified power supply input 132 to the power amplifier 20. The feedback loop for adjusting the power input may be controlled by a power pre-distortion circuit and controller 145. In some configurations, the power pre-distortion circuit and controller 145 and its associated methods may rely on artificial intelligence and machine learning techniques, as shown in FIG. 4 and as described below. In some RF signal jamming devices, it may be beneficial to incorporate both input signal and power control pre-distortion techniques. Incorporation of both such techniques may provide additional synergies.

Referring now to FIG. 4, the drawing discloses an AI-based method of determining appropriate pre-distortion waveform modifications of a signal as well as power control settings to reduce distortion. The method as shown in FIG. 3 comprises collecting a dataset of input/output signal pairs for the power amplifier 310. At least one of the supplied input signals of a set pair should be the originally supplied modulated signal to be amplified by the power amplifier, and at least one of the supplied output signals of a set pair should be the amplified signal that includes any non-linear distortion introduced by the power amplifier. One or more additional set pairs of input waveforms and resultant output amplified waveforms including distortion shall comprise one or more additional set pairs. It is contemplated that one or more set pairs may be based on measurements of real signals supplied as inputs with measurements of real signal outputs from the power amplifier. It is separately contemplated that one or more set pairs may be based on modeled signal inputs and modeled signal outputs based on mathematical models of the power amplifier. It is further contemplated that one or more set pairs may be based on mathematical perturbations of experimental or theoretical signal inputs and their associated mathematically perturbed experimental or theoretical signal outputs.

The complete dataset of signal input/output pairs is then split into a training set and a validation set 320. The training set to be used to train the AI module, and the validation set will be used to evaluate the performance of the model. The training set of data will be used to train an AI model of the performance and behavior of the power amplifier 330. In the case of power control pre-distortion, the model is preferably trained to predict the characteristics of pre-distortion required to be implemented in the input signal that will compensate for the non-linear distortion introduced by the power amplifier 20.

In a configuration of the presently disclosed subject matter, the AI model will use a three-layer neural network that takes inputs and generates outputs. In such a configuration, the first layer is the input layer which has ten nodes representing the symbol peak amplitude, the peak to average power ratio, frequency center, the total signal bandwidth, the modulation spacing, the number of modulation symbols, the symbol hold time, the modulation width of each symbol, and the signal shoulder power level one signal bandwidth in frequency above and below the center frequency as inputs. The second layer has twenty-four (24) intermediate nodes with full population of each input node to each intermediate node. The third layer also has twenty-four (24) intermediate nodes, but only five nodes from the second layer have weights to the nodes below in a manner consistent with design and weighting methods known to those skilled in the art of neural network model development. The fourth layer has eight nodes of the type that is substantially identical to, if not identical to, the input. The training of the network will be to develop a complete model that enables the user to input any signal similar to those used in the training sets and receive an accurate prediction of what the output signal will likely be.

The system can validate the performance of the modeling by using the validation data set 340. The performance of the model can be evaluated by measuring the mean squared value between the predicted pre-distortion signal and the actual pre-distortion signal. The model and associated modeling can be adjusted to minimize error between the predicted and actual signal values 350. Once the models are trained, they can be integrated into the RF signal jamming system 360 and used to develop pre-distortion characteristics that will result in the originally desired (non-distorted) amplified signal as an output.

To develop pre-distortion characteristics for the example embodiment having the neural network model already described, the network is used as a tool without varying the weights and connections of the trained model. In the configuration contemplated, the input signal is provided and allowed to vary any of the inputs, with the output signal monitored for how closely it matches the input signal characteristics other than the desired amplitude increase. The output signal characteristics as defined by the same ten characteristics that define the input, and the variance of each characteristic is given a weighting value in how critical this is to find an optimized solution. The weight of desired amplitude and final signal bandwidth in this example are weighted as five times as valuable as other characteristics with the exception of lower and upper signal strength being weighted as half as important.

The model can be run recursively in a computing device with changes in input signal characteristics modified and the output signal characteristics that result being analyzed for weighted variance from the desired signal. After a designated number of recursive variants, in this case 1,000 iterations permitting both iterative piecewise smooth modifications and up to 10% characteristic jumps to avoid settling in local deviation minima, the recursion is stopped. The final required pre-distorted input signal is presented to the user along with the expected output (intended to closely match the desired output) signal anticipated to result after amplification.

One or more pre-distorted signals developed using the neural network model previously described may be presented to the RF signal jamming system 360 and the output signal measured. If the measured output signal is similar to that predicted by the model, then the training may be considered complete. If the measured output signal is substantially dissimilar to that predicted by the model, then the training may be considered incomplete and additional training sets may be generated experimentally, theoretically, as perturbations, or some combination of additional sets thereof.

It is contemplated that multiple waveforms can be supplied to the model as inputs to predict outputs. The AI model can be used to develop a library of pre-distorted versions of various waveforms as part of a library. Furthermore, the variances from the original input waveforms to the pre-distorted waveforms can be analyzed by a user and/or a separate AI engine to determine common characteristics between the original waveform and their pre-distorted versions. Commonalities could then be programmed into a predictive generation algorithm that could take any desired waveform and develop a pre-distorted version of that waveform that is likely to result in the desired output without using the neural network model and recursion based on characteristic deviation. In at least one embodiment of the presently disclosed subject matter, such a predictive generation algorithm can be used to modify waveforms introduced into a fielded unit such that the newly introduced waveforms will be likely to have low distortion when amplified without any analysis or training of any kind, and the pre-distorted input signals would be generated and amplified without ever testing the newly introduced waveform in its non-pre-distorted form.

Envelope tracking is an additional optimization technique which utilizes real-time power management to improve the efficiency of the power amplifiers in a RF signal jamming device, especially when amplifying signals with high peak-to-average power ratios (PAPR), such as those exhibited by 4G and 5G wireless signals. Such wireless signals are commonly used in association with drones among other devices.

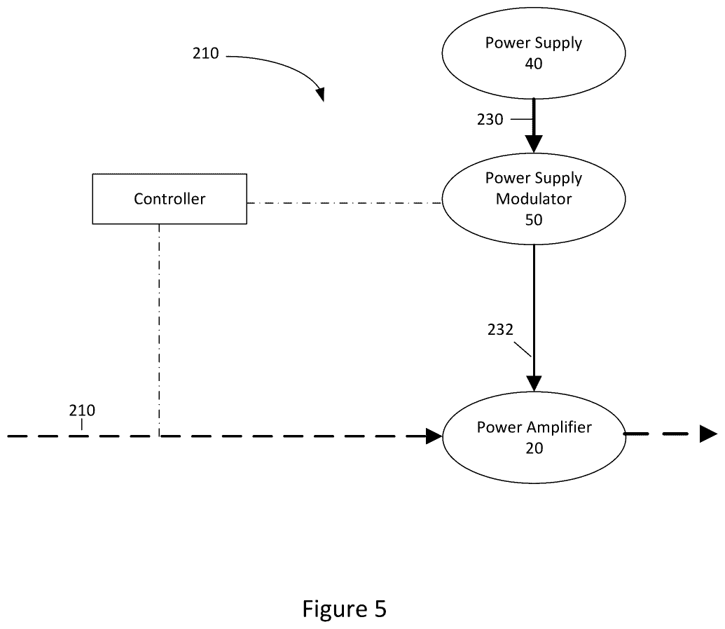

As shown in FIG. 5, envelope tracking 200 can be achieved by adjusting the power supply output 230 to track the envelope of a modulated signal to be amplified 210. This technique includes a power supply modulator 50 that generates a variable DC voltage based on the amplitude of the modulated signal 210, wherein the power supply output 230 is modulated to an ideal power amplifier input 232 which tracks the requirements of the modulated signal to be amplified 210. This variable voltage power input 132 is then supplied to the power amplifier to provide for power usage of improved efficiency as compared to a fixed-voltage system. More specifically, in a system without envelope tracking, a fixed-voltage power supply may, in some circumstances, be set to a voltage level that can accommodate the peak power of an input signal, resulting in a waste of power when the signal is at a lower power level. Envelope tracking 200 does not have such limitations, as envelope tracking provides real-time power supply adjustment.

Machine learning and artificial intelligence may also be implemented in envelope tracking techniques. This may allow power supply modulators to implement models based on large datasets of modulated signals to provide predictive and optimal power supply voltage for any given input signal. AI-powered envelope tracking can also reduce the complexity and cost of the power supply modulator, as the need for complex feedback circuits may be eliminated.

Power sequencing techniques 300 may also be used to manage the power-up and power-down sequencing of the power amplifiers and other various systems of an RF jamming device. Power sequencing circuitry ensures that the power amplifiers and other various equipment systems are controlled in a manner to minimize potential equipment damage, which is often attributed to voltage or current spikes during startup and shutdown. In some instances, power sequencing may protect against damage associated with producing an instantaneous load on a power supply, leading to a drop in voltage supplied to connected electrical components, or may protect against signal or power supply reflections which may occur when enabling/disabling power amplifiers in conjunction with RF transmitting systems and devices.

Power sequencing 300 is accomplished by providing a communication protocol and method for each power supply and power amplifier within an RF signal jamming device or system to electronically communicate with one another. While power supply and amplifying devices are some of the components, it is contemplated that some, most or all hardware and systems of an RF signal jamming device may be connected through a common electronic communication network. In some embodiments, electronic communication may occur by way of a standard ethernet-based network, though other systems, including wireless communication, are contemplated. Power sequencing further includes a protocol or protocols in which hardware, particularly power supplies and amplifiers, receives instructions via the electronic communication network to power on/off in a safe and organized manner to prevent equipment damage. It is contemplated that all hardware systems of an RF signal jamming device may be capable of receiving and sending electronic communication signals or instructions, such signals may include but are not limited to on/off status, power supply conditions (i.e., over-voltage or under-voltage conditions), and temperature.

The power sequencing technique and protocol may be managed and directed by a processor, and/or computing device, embedded within each hardware system of the RF signal jamming device, or may be directed independently by any one processor and/or computing device which is electronically connected to the communication network of the signal jamming device. In some configurations, the protocol may be managed and directed by a user or processor that is remotely located away from the signal jamming device or system which is receiving instructions.

The system and method as discussed herein may also comprise the use of low probability of intercept (LPI) techniques 400 to further optimize RF signal jamming devices. The LPI techniques may include but are not limited to frequency hopping, spread spectrum, low power or short burst transmissions, beamforming, and directional antennas to focus signals in certain directions.

The combination of pre-distortion, AI, and power sequencing techniques provides several advantages over traditional RF signal jamming systems. The AI-powered pre-distortion methodology compensates for non-linear distortion in the power amplifier, allowing it to operate with greater linearity and less distortion. The use of envelope tracking as a pre-distortion technique provides greater efficiency by allowing the power amplifier to operate at a voltage that tracks the amplitude of the modulated signal, reducing wasted power. Power sequencing techniques power up and down the power amplifier in a controlled manner to minimize any potential damage to the power amplifier or other hardware of the RF signal jamming device or system.

The incorporation of AI in addition to the LPI and other above-disclosed processes is valuable because in RF jamming applications, there is a constant need to adapt to different signal frequencies and signal amplitudes as the communication patterns and the like associated with these targets tend to be very different than use in association with wireless communication between devices. By utilizing AI, there can be estimation and adaptability that can be modeled with the assistance with AI.

The system and method disclosed herein can be implemented using a variety of RF signal jamming systems, including military and civilian applications. One such application is in the counter-drone space, wherein the need for quick adaptability is necessary. That is, the communication between the base and the drone is exceedingly different than the communication between cellular devices. Thus, not only does this render the RF signal jamming difficult, but furthermore requires constant adaptation to the elusive communication systems associated with drone communication.

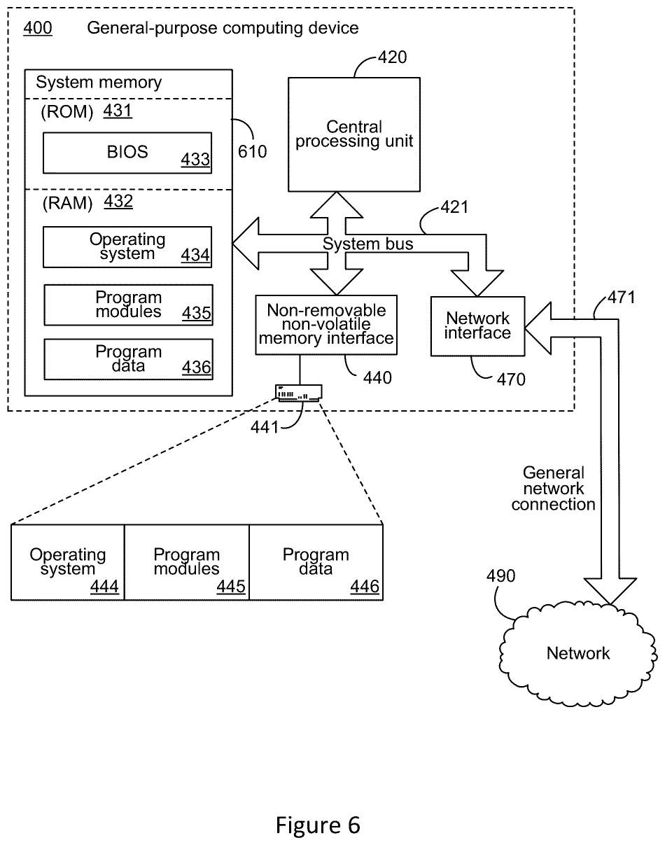

It will be understood that the foregoing may be implemented through the use of a computing device. One such general-purpose computing device is illustrated in FIG. 6 in the form of an exemplary general-purpose computing device 400. As such, it will be described with the understanding that variations can be made thereto. The exemplary general-purpose computing device 400 can include, but is not limited to, one or more central processing units (CPUs) 120, a system memory 430 and a system bus 421 that couples various system components including the system memory to the central processing unit 420. The system bus 421 may be any of several types of bus structures including a memory bus or memory controller, a peripheral bus, and a local bus using any of a variety of bus architectures. Depending on the specific physical implementation, one or more of the CPUs 420, the system memory 430 and other components of the general-purpose computing device 400 can be physically co-located, such as on a single chip. In such a case, some or all of the system bus 121 can be nothing more than communicational pathways within a single chip structure and its illustration in FIG. 6 can be nothing more than notational convenience for the purpose of illustration.

The general-purpose computing device 400 also typically includes computer readable media, which can include any available media that can be accessed by computing device 400. By way of example, and not limitation, computer readable media may comprise computer storage media and communication media. Computer storage media includes media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, cloud data storage resources, video cards, or any other medium which can be used to store the desired information and which can be accessed by the general-purpose computing device 100. Communication media typically embodies computer readable instructions, data structures, program modules or other data in a modulated data signal such as a carrier wave or other transport mechanism and includes any information delivery media. By way of example, and not limitation, communication media includes wired media such as a wired network or direct-wired connection, and wireless media such as acoustic, RF, infrared and other wireless media. Combinations of the any of the above should also be included within the scope of computer readable media.

When using communication media, the general-purpose computing device 400 may operate in a networked environment via logical connections to one or more remote computers. The logical connection depicted in FIG. 6 is a general network connection 471 to the network 490, which can be a local area network (LAN), a wide area network (WAN) such as the Internet, or other networks. The computing device 400 is connected to the general network connection 471 through a network interface or adapter 470 that is, in turn, connected to the system bus 421. In a networked environment, program modules depicted relative to the general-purpose computing device 400, or portions or peripherals thereof, may be stored in the memory of one or more other computing devices that are communicatively coupled to the general-purpose computing device 400 through the general network connection 471. It will be appreciated that the network connections shown are exemplary and other means of establishing a communications link between computing devices may be used.

The general-purpose computing device 400 may also include other removable/non-removable, volatile/nonvolatile computer storage media. By way of example only, FIG. 6 illustrates a hard disk drive 441 that reads from or writes to non-removable, nonvolatile media. Other removable/non-removable, volatile/nonvolatile computer storage media that can be used with the exemplary computing device include, but are not limited to, magnetic tape cassettes, flash memory cards, digital versatile disks, digital video tape, solid state RAM, solid state ROM, and the like. The hard disk drive 441 is typically connected to the system bus 421 through a non-removable memory interface such as interface 440.

The drives and their associated computer storage media discussed above and illustrated in FIG. 6, provide storage of computer readable instructions, data structures, program modules and other data for the general-purpose computing device 400. In FIG. 6, for example, hard disk drive 441 is illustrated as storing operating system 444, other program modules 445, and program data 446. Note that these components can either be the same as or different from operating system 434, other program modules 435 and program data 436. Operating system 444, other program modules 445 and program data 446 are given different numbers here to illustrate that, at a minimum, they are different copies.

The foregoing description merely explains and illustrates the disclosure and the disclosure is not limited thereto except insofar as the appended claims are so limited, as those skilled in the art who have the disclosure before them will be able to make modifications without departing from the scope of the disclosure.

1. A method, stored on a non-transitory medium and executed by a processor for enhancing an RF jamming system, the method comprising the steps of:
pre-distorting an input signal to compensate for non-linear distortion in at least one power amplifier to define a pre-distorted signal;
adjusting a voltage of a power supply of the at least one power amplifier based upon the pre-distorted signal;
power sequencing the at least one power amplifier to power up and power down the at least one amplifier;
adjusting the pre-distorted signal to achieve a low probability of intercept to define an adjusted signal; and
transmitting the adjusted signal.

2. The method of claim 1 wherein the step of pre-distorting further comprises the step of predicting the pre-distortion utilizing machine learning (AI).

3. The method of claim 2 wherein the step of pre-distorting further comprises the step of training the machine learning by providing a dataset of modulated signals to predict an optimal pre-distortion for the input signal to define the pre-distorted signal.

4. The method of claim 2 wherein the step of pre-distorting further comprises the step of utilizing a neural network.

5. The method of claim 1 wherein the step of adjusting the voltage further comprises the step of generating, digitally or analog, a variable voltage based upon the pre-distorted signal;

6. The method of claim 1 wherein the step of adjusting the voltage comprises the step of adjusting the power supply voltage in real-time based upon an amplitude of the pre-distorted signal.

7. The method of claim 1 wherein the step of adjusting the voltage comprises the steps of: tracking an envelope of the waveform and adjusting the power supply voltage in real-time based on at least one characteristic of the envelope.

8. The method of claim 1 wherein the step of adjusting further comprises the step of determining the adjustment utilizing machine learning (AI).

9. The method of claim 1 wherein the step of adjusting the pre-distorted signal to achieve the low probability of intercept comprises at least one of the step of frequency hopping and spread spectrum transmitting.

10. The method of claim 9 wherein the steps of frequency hopping and spread spectrum transmitting are adjusted on a real time basis;

11. The method of claim 1 wherein the step of adjusting the pre-distorted signal to achieve the low probability of intercept further comprises the step of transmitting the adjusted signal through low power or the step of transmitting the adjusted signal through short burst transmissions.

12. The method of claim 1 wherein the step of adjusting the pre-distorted signal to achieve the low probability of intercept further comprises the step of focusing the adjusted signal through the use of directional antennas.

13. The method of claim 1 wherein the step of adjusting the pre-distorted signal to achieve the low probability of intercept further comprises the step of applying beamforming to, in turn, reduce detectability of the adjusted signal when transmitted.

14. The method of claim 1 further comprising the step of generating a modulated signal through the use of a signal generator prior to the step of pre-distorting, and wherein the modulated signal is the input signal.

15. The method of claim 14 wherein the modulated signal includes multiple channels.

16. The method of claim 1 wherein the step of pre-distorting further includes the step of adapting to at least one change in the at least one power amplifier.

17. The method of claim 1 wherein the step of pre-distorting further includes the steps of:
monitoring an output of the at least one power amplifier; and
adjusting the pre-distorting based upon the monitored output of the at least one power amplifier.

18. The method of claim 1 wherein the step of adjusting the voltage and the step of power sequencing utilize digital signal processing.

19. The method of claim 1 wherein the step of power sequencing further comprises the step of preventing an overshoot and an undershoot.

20. The method of claim 16 wherein the step of preventing an overshoot and an undershoot further comprises the steps of smoothly ramping up and smoothly ramping down the at least one power amplifier.

21. The method of claim 1 wherein the input signal may comprise a plurality of input signals, resulting in a plurality of pre-distorted signals and a plurality of adjusted signals.

22. A system for enhancing an RF jamming system, the system comprising:
a pre-distorting module structurally configured to pre-distort an input signal to compensate for non-linear distortion in at least one power amplifier to define a pre-distorted signal;
a voltage adjuster structurally configured to adjust the voltage of a power supply of the at least one power amplifier based upon the pre-distorted signal;
a power sequencer structurally configured to sequence the at least one power amplifier to power up and power down the at least one amplifier;
a low probability of intercept module structurally configured to adjusting the pre-distorted signal to define an adjusted signal; and
a transmitter structurally configured to transmit the adjusted signal.

23. A method, stored on a non-transitory medium and executed by a processor for enhancing an RF jamming system, the method comprising the steps of:
pre-distorting an input signal to compensate for non-linear distortion in at least one power amplifier to define a pre-distorted signal utilizing machine learning (AI);
adjusting a voltage of a power supply of the at least one power amplifier based upon the pre-distorted signal utilizing machine learning (AI);
power sequencing the at least one power amplifier to power up and power down the at least one amplifier;
adjusting the pre-distorted signal to achieve a low probability of intercept to define an adjusted signal; and
transmitting the adjusted signal.
